(19) United States
(12) Patent Application Publication
(10) Pub. No.: US 2023/0242261 A1
(43) Pub. Date: Aug. 3, 2023

(54) PIEZO DE-ICING AND ANTI-ICING SYSTEMS AND METHODS

(71) Applicant: MEGGITT AEROSPACE LIMITED, COVENTRY (GB)

(72) Inventors: Rasmus Lou-Moeller, Coventry (GB); Marc Emery, Coventry (GB); Michael Sanders, Coventry (GB); Nikolaj Agentof Feidenhans'l, Coventry (GB); Vincent Trole, Coventry (GB); David Warriner, Coventry (GB); Chris Davies, Coventry (GB)

(21) Appl. No.: 17/587,624

(22) Filed: Jan. 28, 2022

(51) Int. Cl. B64D 15/16; H04R 17/10; H01L 41/053; H01L 41/09

(52) U.S. Cl. CPC B64D 15/163; H04R 17/10; H01L 41/053; H01L 41/09; H02M 3/1582

(57) ABSTRACT

A method of deicing an airfoil is provided. In preferred embodiments, the method comprises coupling a plurality of piezo-electric transducers (PETs) to an inside surface of an airfoil. The PETs are electrically coupled to a DC-DC converter and a first inverter. The PETs are driven by sweeping the driving frequency of the plurality of PETs over a frequency range that spans at least 10 kHz and 100 kHz. In preferred embodiments, some PETs are driven at a phase shift to the other PETs.

### FIELD

The present patent document relates generally to piezoelectric driven de-icing and/or anti-icing systems and methods of using and making the same. More specifically, the present patent document relates to piezoelectric de-icing and/or anti-icing systems for aircraft and aerodynamic surfaces and methods of using and making the same.

### BACKGROUND

In flight icing has detrimental effects on the flying characteristics of an aircraft. Ice accumulation can decrease lift and thrust, and increase drag and weight. Aircraft icing is caused by super-cooled water droplets striking the airfoil leading edge and freezing on impact. For numerous reasons, it is important that a significant amount of ice is never allowed to form on an aircraft. More importantly, if ice builds up on the aerodynamic surfaces, it could affect the performance of the aircraft, the handling qualities and even could lead to loss of control.

The fundamental concept behind the ultrasonic de-icing approach is to generate shear stresses in the structure that exceed the ultimate shear adhesion strength of a layer of accreted ice. The adhesion strength of the ice varies depending on temperature, type of ice, and type of structure the ice is adhered too. The ultrasonic method of deicing is based on the fact that the adhesion shear forces between ice and the surface of the aircraft skin are relatively small. Therefore, the ice layer can be delaminated by applying shear stress at the interface of the skin material. To achieve de-icing effect, the stress generated must exceed the adhesion shear strength of the ice layer.

Numerous deicing systems are known in the art including both electro-thermal wing ice protection systems and piezoelectrical deicing systems.

In operation, electro-thermal wing ice protection systems represent one of the most significant electrical loads on the electrical generation system. A main wing fully evaporative anti-ice electro-thermal system for a mid-size passage transport category aircraft would require between 120 kW and 200 kW.

Piezoelectric deicing systems should provide power savings over electro-thermal systems. There are some piezoelectrical deicing systems known in the art such as the ones taught in U.S. Pat. Nos. 4,545,553 and 4,732,351.

Despite this knowledge, adoption and implementation of piezoelectric deicing and anti-icing systems to commercial aircraft has yet to occur. This is because the current systems and methods have too many problems with their implementation and performance to be viable solutions. Existing electro-mechanical deicing systems are considered unattractive because they required too much power, have high installation weights and high acquisition costs. Accordingly, what is needed are deicing and anti-icing systems that use piezoelectric transducers and can be reliably and successfully implemented. The teachings herein provide such a solution.

### SUMMARY OF THE EMBODIMENTS

Objects of the present patent document are to provide improved piezoelectric deicing systems and/or anti-icing systems and methods of using and making the same. In preferred embodiments, the ice protection systems protect surfaces of the wing against the accretion of ice that would negatively impact the handling qualities of the aircraft. Ice protection systems may further provide protection for FOD purposes, such as in the case of potential damage to rear mounted engines from detaching ice chunks. To this end, in one embodiment, a method of deicing an airfoil is provided. In preferred embodiments, the method of deicing an airfoil comprises: coupling a plurality of piezo-electric transducers (PETs) to an inside surface of an airfoil. The PETs are electrically coupled to a DC-DC converter and a first inverter. The first inverter is controlled to drive the plurality of PETs over a frequency range that spans at least 10 kHz-100 KHz.

In some embodiments, the plurality of PETs is divided into a first group and a second group and the first group is electrically coupled to the first inverter and the second group is coupled to a second inverter. The first inverter drives the first group at a phase shift to the second inverter driving the second group. In some embodiments, the phase shift is 180 degrees. In other embodiments, other amounts of phase shift may be used. In some embodiments, the amount of phase shift is repeatedly changing.

In preferred embodiments, the power supply is a buck converter operated as a current source. In other embodiments, other power supply configurations can be used such as a buck boost converter or a forward converter or any combination of the converters mentioned.

In some embodiments, the inverters are half bridges. In other embodiments, a full H-bridge can be used.

Generally speaking, the PETs can be designed in any shape. As discussed in detail herein, preferred embodiments use PETs in the shape of a disc. The discs can be any size or shape but in preferred embodiments, the discs have a diameter of 50 mm±2 mm. In even more preferred embodiments, the discs have a thickness of 2 mm±0.1 mm.

The PETs may be driven with various different shaped waves, including but not limited to square waves, sine waves, triangular waves and various other shaped waves. In preferred embodiments, the PETS are driven with a sine wave voltage signal. In yet other embodiments, a square wave may be used.

In another aspect of the deicing systems discussed herein, a method of coupling a piezo-electric transducer (PET) to an airfoil if provided. In preferred embodiments, the PETs are coupled to the airfoil by adhering an electrically insulating composite patch to an inside surface of the airfoil. Then an electrically conductive sheet is adhered to a first bottom electrical conductor of the PET using a conductive epoxy. A second bottom of the PET and a third bottom of the electrically conductive sheet is adhered to a top of the insulating material using a non-conductive epoxy. A first electrical lead is electrically coupled to the electrically conductive sheet and a second electrical lead is electrically coupled to a top conductor of the PET.

In preferred embodiments, the electrically conductive sheet is copper foil. In other embodiments, typical aircraft standard connections are used.

In preferred embodiments, the PET is disc shaped. In more preferred embodiments, the PET has a diameter between 40 mm and 60 mm. In still yet other embodiments, the PET has a thickness of between 1.75 mm and 2.25 mm.

### BRIEF DESCRIPTION OF THE DRAWINGS

FIG. 1 provides a high-level, graphical depiction of a piezoelectric based deicing system, the external entities it interacts with, and those interactions;

FIG. 2 illustrates a schematic of an embodiment with a master controller and satellite controllers on the leading edge;

FIG. 3 schematically illustrates another embodiment of a piezo-electric deicing system in which a single centralized controller is used;

FIG. 4 schematically illustrates another embodiment 15 of a deicing system with the implementation integrated within the IMA environment;

FIG. 5 illustrates five different potential actuator configurations for the wing of an aircraft;

FIG. 6 illustrates a disc shaped PET actuator for use in a deicing system;

FIG. 7 illustrates a bonding method for use in attaching the actuators to the aircraft skin;

FIG. 8A illustrates an H-bridge connected to a piezo-electric transducer;

FIG. 8B illustrates an electrical schematic for driving a PET;

FIG. 9 illustrates an embodiment with a plurality of transducers electrically connected to a single bridge;

FIG. 10A illustrates the average de-icing performance of a plate versus a disk transducer over the entire frequency range;

FIG. 10B illustrates the average de-icing performance of a plate versus a disk transducer of FIG. 10A but scaled to the area of the transducers;

FIG. 11A illustrates a summary of the comparison data of FIGS. 10A and 10B when the frequency is swept through the entire frequency range;

FIG. 11B represents the data in FIG. 11A but scaled to the area of the transducer;

FIG. 12A illustrates the performance of different diameter piezoelectric discs;

FIG. 12B illustrates the data of FIG. 12A scaled by disc volume;

FIG. 13A illustrates the performance of different thickness piezoelectric discs;

FIG. 13B illustrates the data of FIG. 13A scaled by disc volume;

FIG. 14 illustrates the impedance spectrum of two free standing PET discs of 38 mm and 50 mm diameters;

FIG. 15 illustrates impedance spectrum of a 38 mm diameter disc attached to the airfoil in different conditions;

FIG. 16 illustrates the change in frequency response between an unbonded and bonded 50 mm PET disc;

FIG. 17 illustrates the de-icing efficiency of 38 mm PET discs with a 1 mm thickness;

FIG. 18 illustrates the de-icing efficiency of 50 mm PET discs with a 2 mm thickness;

FIG. 19A shows an example of a leading edge with ice accretion;

FIG. 19B shows the leading edge of FIG. 19A with ice cracking;

FIG. 20 illustrates a cross-section view of an airfoil with a plurality of PETs attached to the inner skin;

FIG. 21 illustrates a cross-section of the attachment of the PET 40 to the airfoil.

### DETAILED DESCRIPTION OF THE PREFERRED EMBODIMENTS

The present patent document discloses embodiments of deicing and/or anti-icing systems for surfaces and in particular for aerodynamic surfaces and methods of making and using the same. Embodiments disclosed herein perform deicing/anti-icing by applying to the surfaces, shear-stresses of sufficiently great levels, in order to create sufficient local acceleration levels (in x, y and/or z axis) in order to shed, and/or prevent the growth of ice. In all the embodiments herein, ultrasonic piezoelectric transducers are used for creating the shear-stresses needed to remove the ice or prevent new ice from forming.

In comparison to electro-thermal ice protection de-ice systems, piezoelectric ice protection systems may provide a power saving of better than 90%.

The fundamental items of the piezoelectric effect ice protection system are: 1.) PET actuators; 2.) power controller; and 3.) PET actuation control including channel control through application voltage, frequency, frequency sweep, phase shift and sequence control through the scheduling of different actuators; and 4.) the impact of appropriate special separation or spacing of the PETS.

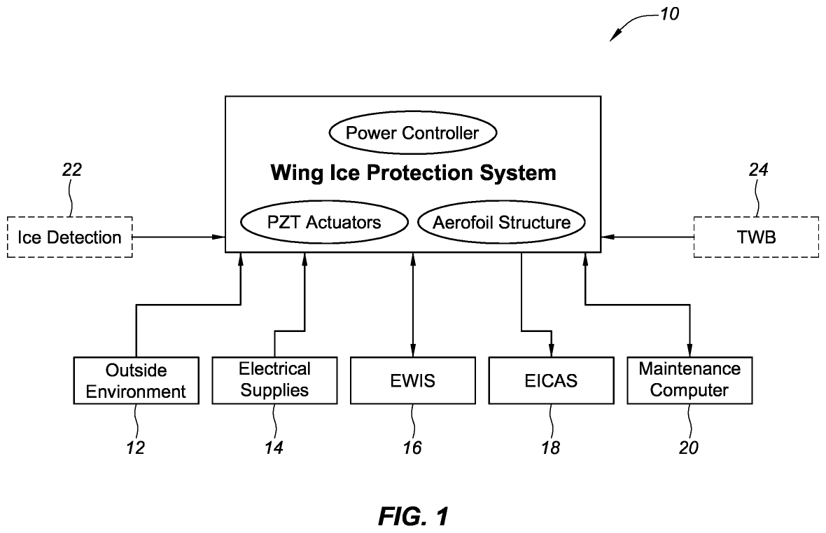

FIG. 1 provides a high-level, graphical depiction (context diagram) of a piezoelectric based deicing system, the external entities it interacts with, and those interactions. The external entities are: 1). outside environment 12, a.k.a., the ambient conditions that the aircraft operates in and in particular the inflight icing threat that the system is designed to protect against; 2.) electrical supplies 14, aircraft electrical power used by the system to implement ice protection; 3.) wiring 16, cables used to transport electrical signals within and outside the ice protection system; 4.) Engine Indication Crew Alerting System (EICAS) 18, the interface with the engine indication and crew alert systems; 5.) maintenance computer 20, provides data to the aircraft for the purposes of maintenance and condition monitoring; 6.) ice detection 22, provides identification (icing parameters) of the icing threat; and 7.) Travelling Wire Bundle (TWB) 24, cable management for moveable aircraft surfaces (slats).

Preferred embodiments of the PET ice protection system may comprise: 1.) an array of Piezo-electric actuators, or a Piezo-electric film, located within the wing leading edge structure; 2.) a power supply for the PET actuators; 3.) an interface to the aircraft systems (air data/external environment and ice detection); 4.) the capability to provide the status of the ice protection system to the aircraft; 5.) the capability to provide maintenance and troubleshooting data; 6.) an aircraft structure that does not prohibit the excitation mechanism but still allows integration of key technologies e.g. lightning strike protection and meets design requirements e.g. bird strike; 7.) Electrical Wiring Interconnect System (EWIS) wiring system required to pass signals to the system components.

In the various different embodiments, the PET deicing system may be controlled in a number of ways. In some embodiments, there is a Master Controller with satellite power controllers located at the wing leading edge. In another embodiment, a single centralized controller may be used. In still yet other embodiments, the system may be integrated with the integrated modular avionics (IMA) environment.

Different configurations may also be used for the PET actuators. In some embodiments, an array of piezo-electric films, each one having its dedicated power controller, may be used. In some embodiments, each Piezo-electric actuator includes its proper power supply (=array of PET actuators with a simple command: ON or OFF).

In some embodiments, the PETs could only have a simple ON/OFF controller. In such an embodiment, all piezo-electric actuators are supplied power at the same time. This is a less complex solution and could be sufficient if the total power consumption is not too high. In other embodiments, more sophisticated control of individual PET actuators could be provided. For example, individual actuators could be controlled ON/OFF. In other embodiments, groups of actuators may be controlled ON/OFF. In still yet other embodiments, individual actuators may have their own power control such that some actuators could be driven harder or softer than others. More complicated controls could increase complexity but have the advantage of the ability to decrease power consumption by allowing use of only the necessary actuators at any given time.

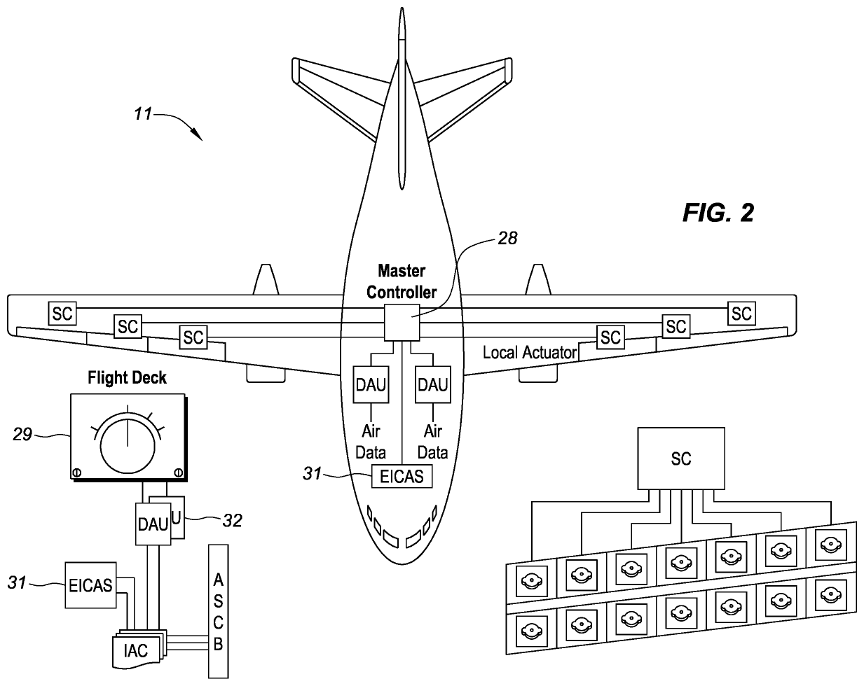

FIG. 2 illustrates a schematic of an embodiment 11 with a master controller and satellite controllers on the leading edge. As may be seen in FIG. 2, the embodiment 11 comprises a master controller 28 that interfaces with the: 1.) EICAS 31; 2.) flight deck for system command 29 through the aircraft avionics network; 3.) air data system 32 and ice detector (if available) through data acquisition units (DAU); and 4.) the local satellite power controllers (LSPC).

The LSPC is designed to interface with the master controller 28. The LSPC receives instructions for voltage and frequency from the master controller 28 and applies it to the actuators. The LSPC interfaces with a local array of PET actuators located on the leading edge structure and applies the required voltage, frequency and sequencing to the actuators.

The PET actuators interface with the LPSC and receive voltage/frequency signals to generate shear stresses within the protected structure. As may be seen in FIG. 2, actuators may be grouped into arrays. Actuator array groups may be positioned in multiple places along the wing. In the embodiment shown, three actuator arrays are used on each wing. In other embodiments, more or fewer arrays may be used. In preferred embodiments, each actuator array is positioned between a wing spar. In the embodiment shown in FIG. 2, each actuator array has 14 actuators. However, in other embodiments, actuator arrays may have more or fewer actuators. In preferred embodiments, actuator arrays have between 2 and 50 actuators. In more preferred embodiments the actuator array has between 10 and 20 actuators.

In operation, the pilot selects the system mode (Off, On, Test, Auto). In ‘Auto’ the system is commanded by an external environmental system such as a ‘Primary Automatic Ice Detection System’. The Master Controller receives aircraft air data, calculates the required icing sequence and commands the LSPC to activate the PET actuators in the required sequence. The PET actuators then create the shear stresses within the protected structure. Signal and control transmission is provided though EWIS.

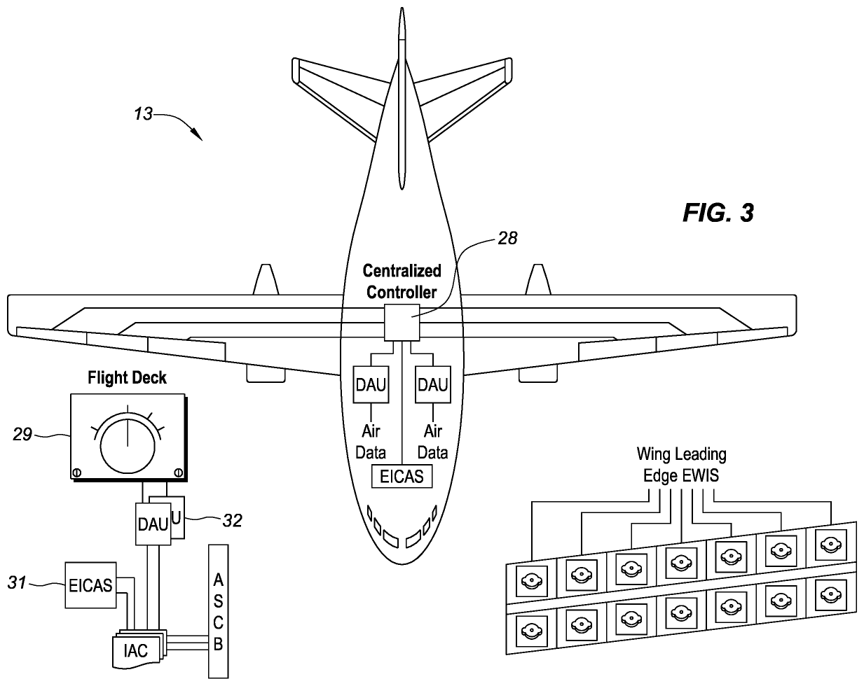

FIG. 3 schematically illustrates another embodiment 13 of a piezo-electric deicing system in which a single centralized controller is used. The only major different between the embodiment 13 in FIG. 3 with the single centralized controller and the embodiment 11 in FIG. 2 is that the embodiment 13 in FIG. 3 does not use LSPCs. The LSPC function is contained within the centralized controller.

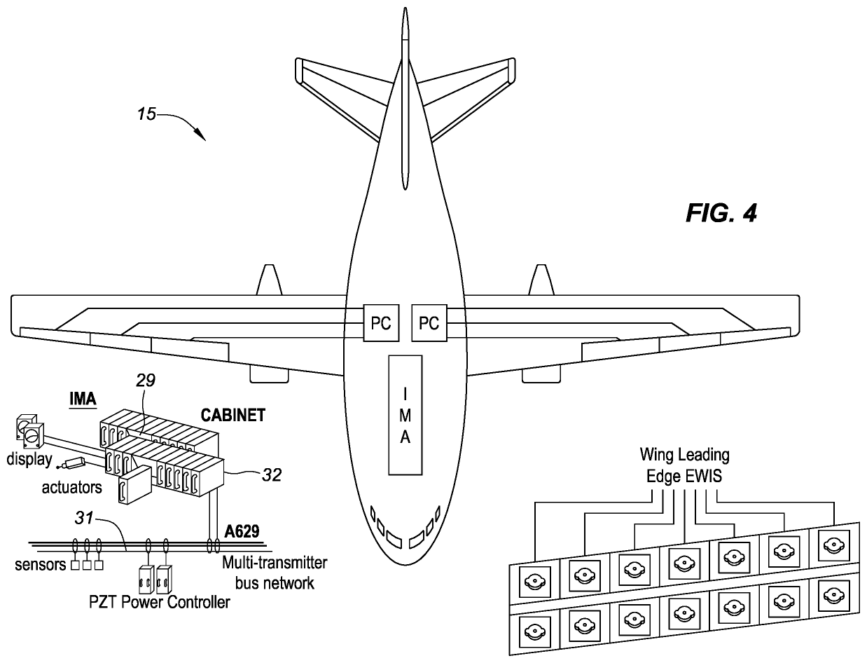

FIG. 4 schematically illustrates another embodiment 15 of a deicing system with the implementation integrated within the IMA environment. In the IMA embodiment, numerous separate processors and line replaceable units are replaced with fewer, more centralized processing units. In the IMA embodiment, the IMA modules replace the master controller 28. However, the unique function of power controller with the ability to vary both voltage and frequency cannot be incorporated within an IMA environment.

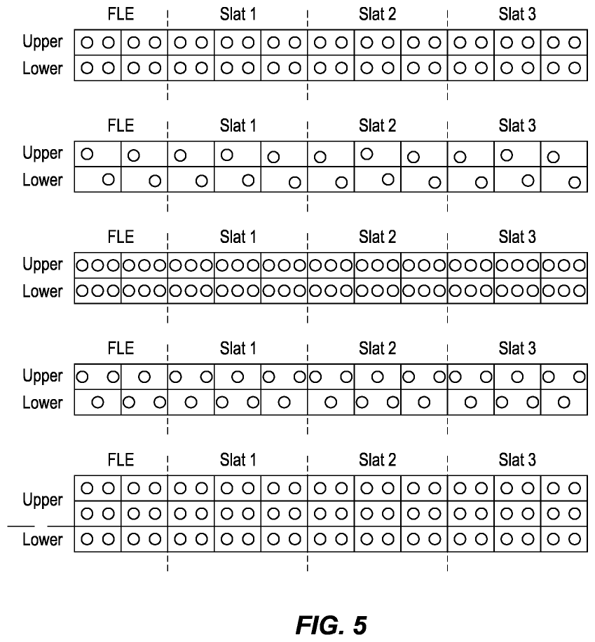

An important factor in how well a piezoelectrical deicing system works is the deployment of the actuators. FIG. 5 illustrates five different potential actuator configurations for the wing of an aircraft. The PET actuator density and the associated number of power controller (Buck Converters/Current Inverters) required to meet deicing performance may have a significant impact of the life cycle costs.

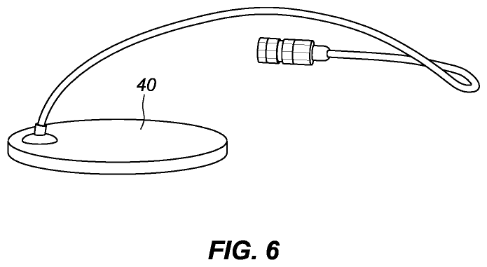

FIG. 6 illustrates a disc shaped PET actuator 40 for use in a deicing system. As will be explained in more detail later, disc shaped PET actuators are preferred.

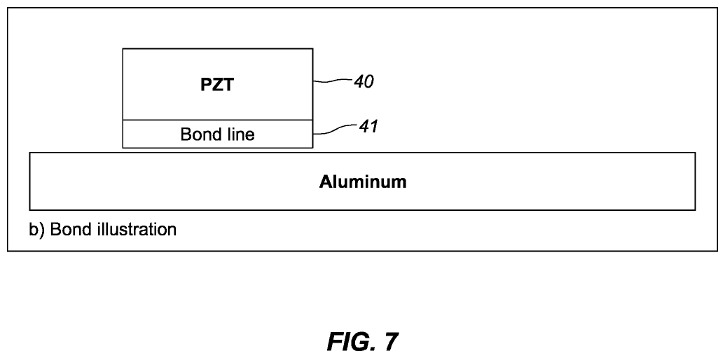

FIG. 7 illustrates a bonding method for use in attaching the actuators to the aircraft metallic skin. In order to be effective, the bond line 41 needs to be very thin and not dampen the sheer stresses produced by the actuator 40. The thickness will vary along the bond line, both due to the curvature of the aerofoil and the different layers (copper foil, etc.) The thickness will be between 0.1 and 0.35 mm. In embodiments where the aircraft skin is a composite, other methods may be used.

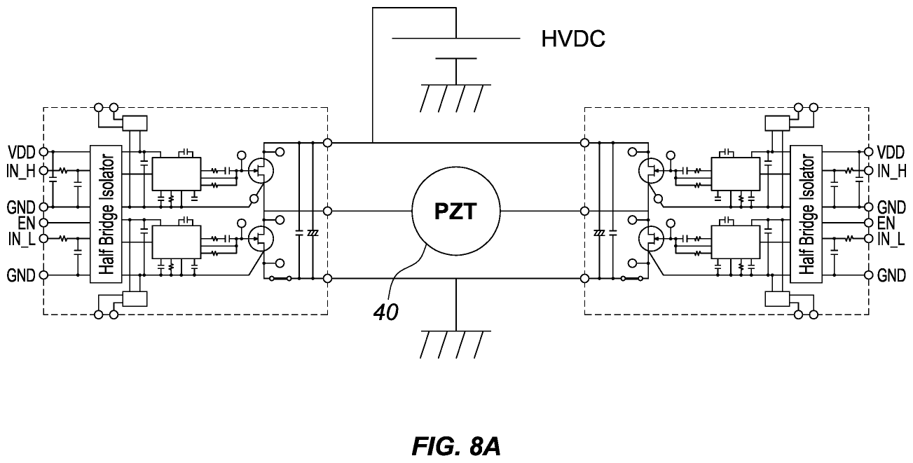

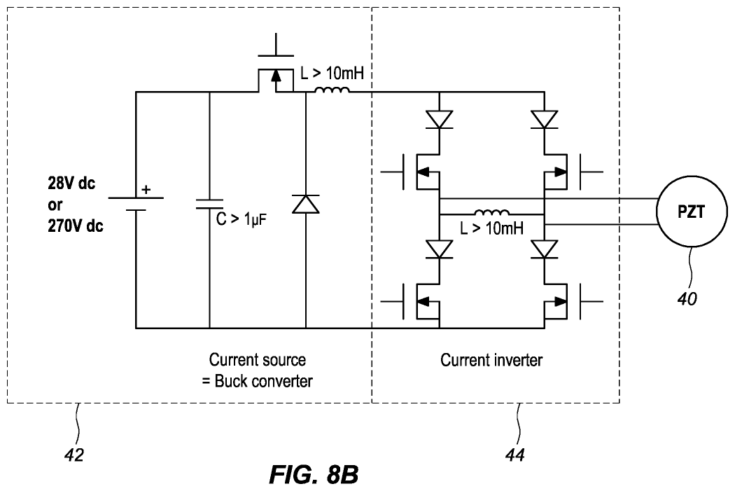

In preferred embodiments, the driver for the actuator can be a full H-bridge or Buck Converter coupled to a current inverter. FIGS. 8A and 8B illustrates examples of each. FIG. 8A illustrates an H-Bridge connected to a piezo-electric transducer. The H-Bridge allows ±HVdc pulses to be applied to the PET actuator. The PET actuator then operates in a tensile mode followed by a compressive mode. FIG. 8B illustrates a Buck Converter coupled to a current inverter connected to a piezo-electric transducer.

As may be seen in FIG. 8B, the transducer driving system may consist of Buck converters and current inversion. This enables the interface between the HVDC from the aircraft and the piezo power supply, generating the appropriate current and voltage values and waveform. The system enables constant current regulation, power efficiency and minimum EMI, while remaining relatively simple.

The amount of power needed to fully de-ice the leading edge of the airfoil should be optimized for each type of PET. The bigger PETs induce more stresses than small discs for the same amount of power.

The piezoelectric transducers can be excited with square wave input signal, where square waves are preferred from an electrical design perspective, in order to produce a symmetric output power. The voltage is fixed by the system design and PET geometry, 270V for example in an aircraft, which implies that the PET will only be in expansion mode.

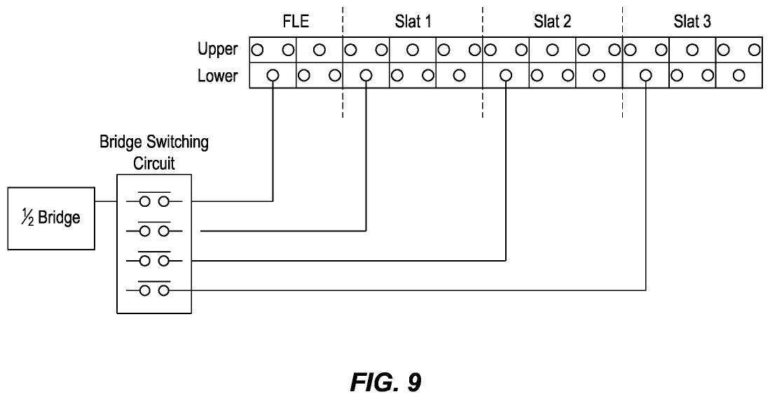

FIG. 9 illustrates how the number of bridges required to implement the icing solution may be reduced. As may be seen in FIG. 9, a plurality of actuators is attached to single Power source by power distribution box that allows multiple PET to be actuated by the one power source. The assumption for the illustration is that each PET actuator is not required to be operated simultaneously. There are of course other combinations and alternatives that could be implemented.

In addition to the piezo-electric active ice systems described herein, embodiments may additionally use passive ice protection measures. For example, ice phobic coatings and their ability to reduce ice adhesion are important. The intention being that the adhesion between the ice and the airfoil surface is decreased due to the beneficial effect of the coating and the electrical power to operate an active system is reduced. To this end, embodiments of piezoelectric deicing systems may include ice phobic coatings to increase effectiveness and reduce mechanical deicing requirements. In addition, active electro-thermal heating may also be added to piezo-electrical deicing systems. Systems stand to benefit from the combination of the attributes of the piezoelectric effect, ice phobic coatings and electro-thermal protection at the highlight of a leading edge.

The piezoelectric transducer (PET) is the active component in the de-icing system, and is responsible for providing the mechanical stresses that break and delaminate the ice. Piezoelectric materials are ceramic materials that generate an electrical charge in response to an applied mechanical stress, this is called the piezoelectric effect, while the opposite process from electrical to mechanical energy, is called the converse effect. An important feature of a PET is the resonance frequency, which is the frequency where there is a resonance between the electrical excitation and mechanical movement. At this frequency, there is a maximum in the energy conversion; hence a PET is typically driving at, or close to, this frequency.

Bonding a PET to an airfoil and exciting it with an AC field, results in the generation of mechanical waves propagating in the airfoil. When the waves reach the ice-airfoil interface the resulting shear stresses can both break and de-bond the accreted ice. The stress magnitude is highly frequency dependent, due to the effects of the PET resonance described above.

Not surprisingly the shape of the PET has a significant impact on the performance, as well as the main features of the geometry, such as the characteristic length and thickness. The characteristic length determines the resonance frequencies of the planar mode, while the thickness affects the stress level induced by the PET into the substrate. Examples of characteristic length would be the diameter of a disc and the side length of a rectangular shaped PET.

Although any size and shape piezoelectric element may be used for deicing, the Applicant has learned through extensive experimentation that the optimum geometry of a PET transducer for de-icing application on an airfoil is a disc with an electrode on the top and bottom surface. From simulation, it seems that the disc shaped PET provides the largest stresses on the leading edge. However, later design optimizations for other airfoil profiles might result in other considerations for choosing the best geometry. Accordingly, embodiments herein are not limited to a particular geometry and other geometries are possible.

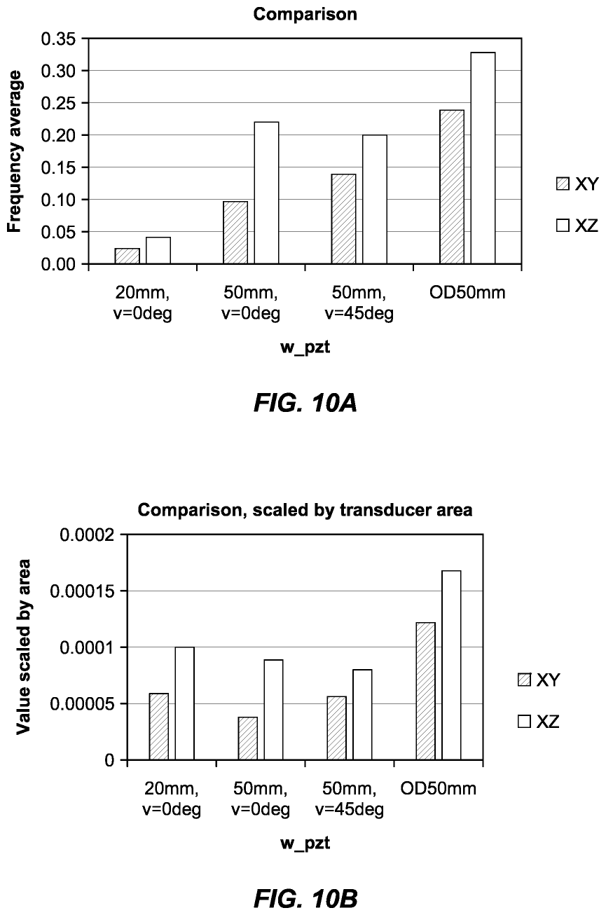

FIGS. 10A and 10B illustrates the outcomes of the finite element method (FEM) modelling analysis of plate versus disk geometries of piezoelectric transducers for use in deicing applications. FIGS. 10A and 10B illustrates the average “de-icing performance” of the two different geometries. FIG. 10A illustrates the average de-icing performance of a plate versus a disk transducer over the entire frequency range. FIG. 10B illustrates the average deicing performance of a plate versus a disk transducer of FIG. 10A but scaled to the area of the transducers.

The ice removal performance is evaluated from the stresses generated in the interface between the ice and the aluminum plate. A threshold value is set for both the XY (cracking) and ZX (delaminating) stresses and then the total area of the interface where the stresses exceed the threshold is determined. This provides a single number for the “de-icing performance” at each frequency. A comparison of the “de-icing performance” for the different geometries is obtained and summarized into a single value, by obtaining the average “delamination area” over the entire frequency range.

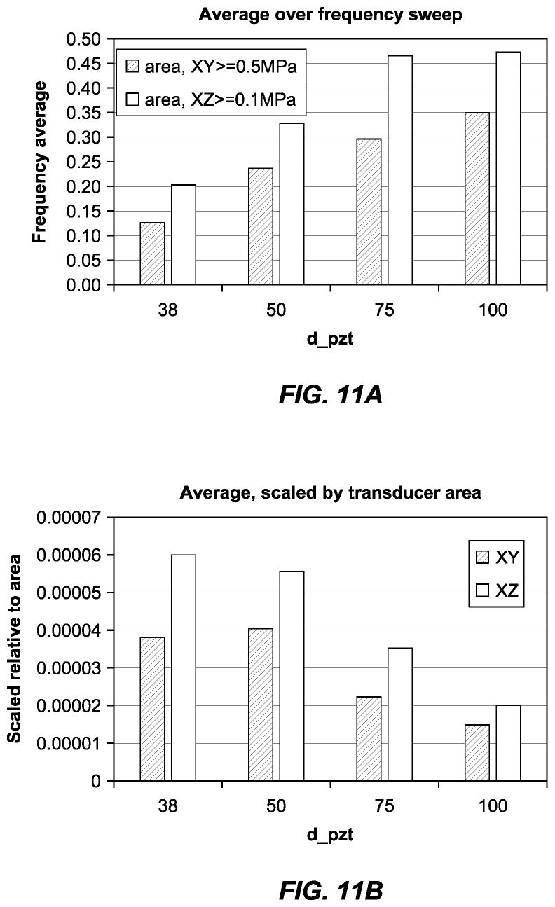

FIGS. 11A and 11B illustrate a summary of the comparison data when the frequency is swept through the entire frequency range. In FIG. 11A, the bars represent the average of the relative areas obtained over the entire frequency sweep. In FIG. 11B, the bars represent the data in FIG. 11A but scaled to the area of the transducer.

The inferior performance of the plates is attributed to the volume of “dead” ceramic in the corners of the plates. This region is more heavily clamped by the bonding to the aluminum substrate. In contrast, the disc can expand in a more symmetric pattern around the center.

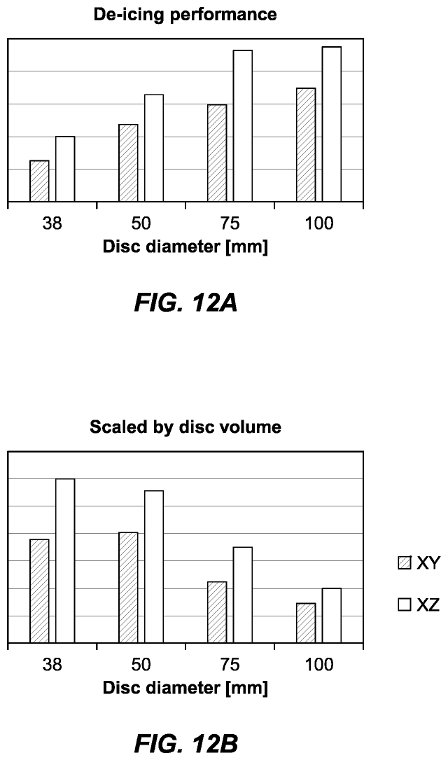

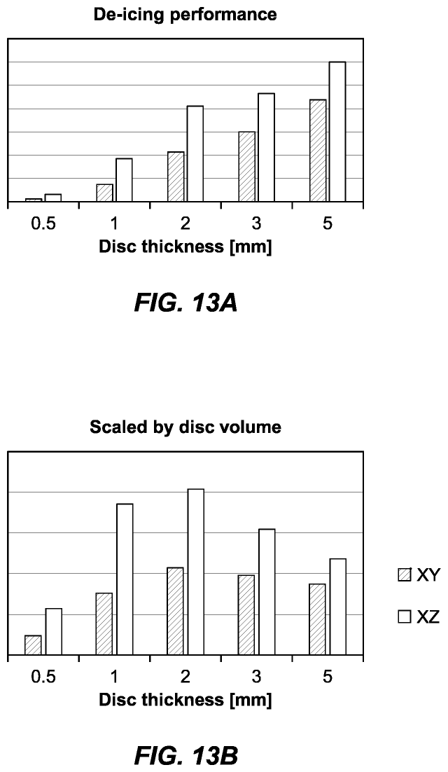

With the general shape defined as a disc, further investigations were performed by FEM simulations regarding the optimization of the diameter and thickness. FIG. 12A illustrates the performance of different diameter discs and FIG. 12B illustrates the data of FIG. 12A scaled by disc volume. Similarly, FIG. 13A illustrates the performance of different thickness discs and FIG. 13B illustrates the data of FIG. 13A scaled by disc volume.

Not surprisingly it was found that, to provide the best de-icing performance, the discs should simply be large and thick. However, when also considering the transducer mass by scaling the values with the volume, a trend is seen towards smaller discs. For the case of multiple transducers bonded to an airfoil, many small discs will achieve a better de-icing effect than a few big discs. Tests and experimentation show a plurality of smaller discs achieve the optimal de-icing effect.

Although any geometry may be used for the PET transducer in deicing applications, it has been determined that a disc of approximately 50 mm diameter, preferably between 40 mm and 60 mm, and more preferably between 45 mm and 55 mm, is optimal. It has further been determined that a disc thickness of approximately 2 mm, between 1.5 mm and 2.5 mm, and more preferably between 1.75 mm and 2.25 mm is optimal. Accordingly, the optimal geometry of the PET transducer is a disc of 50 mm diameter and 2 mm thick.

Structures with different stiffness's or manufactured from different materials will require different control laws to ensure that the resonance frequency is excited across a range of ice types and build ups. These variations will include the range of the frequent sweep and the rate at which the frequency sweep occurs.

In preferred embodiments, the transducers are excited in their planar mode corresponding to in-plane movement of the disc, whose resonance frequency is determined by the transducers' diameter and the associated structural characteristics

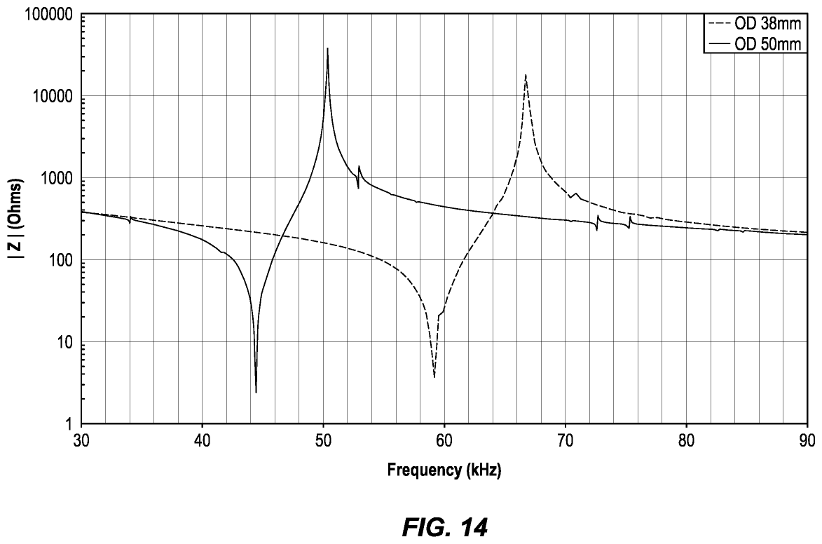

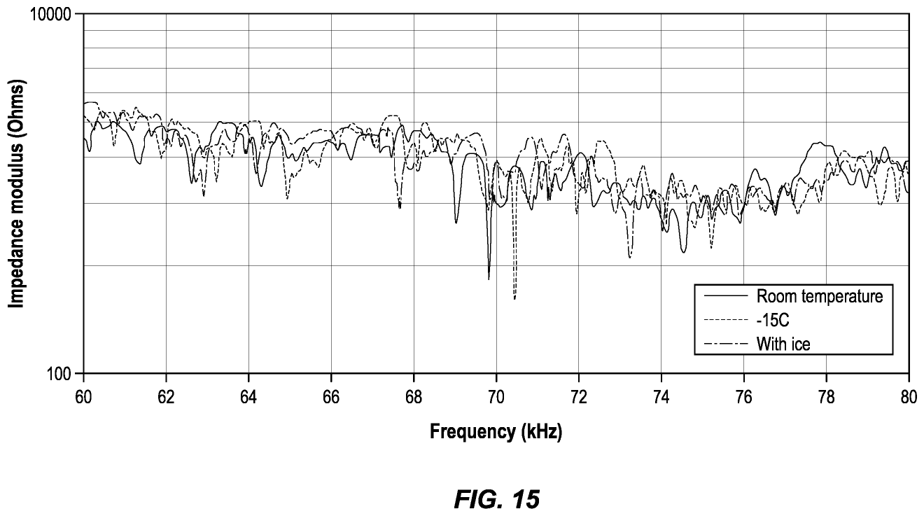

As the disc diameter increases, the resonance frequency shifts to lower frequencies. FIG. 14 illustrates the impedance spectrum of two free standing PET discs of 38 mm and 50 mm diameters. The resonance frequency is linked to the dimensions of the PET, for example a 50 mm diameter disc has its resonance at 45 kHz, while for 38 mm diameter disc it is at 59 kHz. It can be seen in FIG. 15 how the resonance frequency shifts lower as the disc diameter increases.

Frequency sweep and phase inversion is employed to provide an improvement in the shear stress coverage levels.

The bonding of the PET disc to the airfoil perturbs the mechanical environment of the transducer, i.e. there is not a single resonance frequency as seen previously but several small resonances, at which the transducers need to be excited. Moreover, the frequency response is also affected by temperature and the accretion of ice on the wing. Accordingly, the impedance spectrum is completely disrupted when the PET is bonded to the airfoil and when an ice layer is accreted on the leading edge. FIG. 15 illustrates impedance spectrum of a 38 mm diameter disc attached to the airfoil in different conditions. As one can observe on FIG. 15, the impedance spectrum at room temperature (green) is very different from the curve in FIG. 14. Moreover, some frequency shift occurs when the temperature is changed and with the presence of ice.

Due to the influence of these many factors, it would be impossible to determine the resonance frequency and excite the PET at this precise frequency, since the system will constantly change. As a consequence, frequency sweeping is found to be a more viable alternative solution than fixed frequency excitation. The frequency of the input signal is then swept over a defined range of frequency for a certain period of time. Several sweeps can then be performed in a row, and by monitoring the output voltage and current from the driving system, it will be possible to narrow down the frequency range to the most effective range, since the ice cracking events are known to correlate with the power consumption. In addition, current experiments have shown that the cracks generally appear when the frequency is changed, thus exciting the PET at the same frequency will not lead to further cracking, while exciting at a slightly higher or lower frequency will. In preferred embodiments, the range of the frequency sweep is from 10 kHz to 100 KHz, with a 5-10 KHz range within this frequency band being swept at any one time.

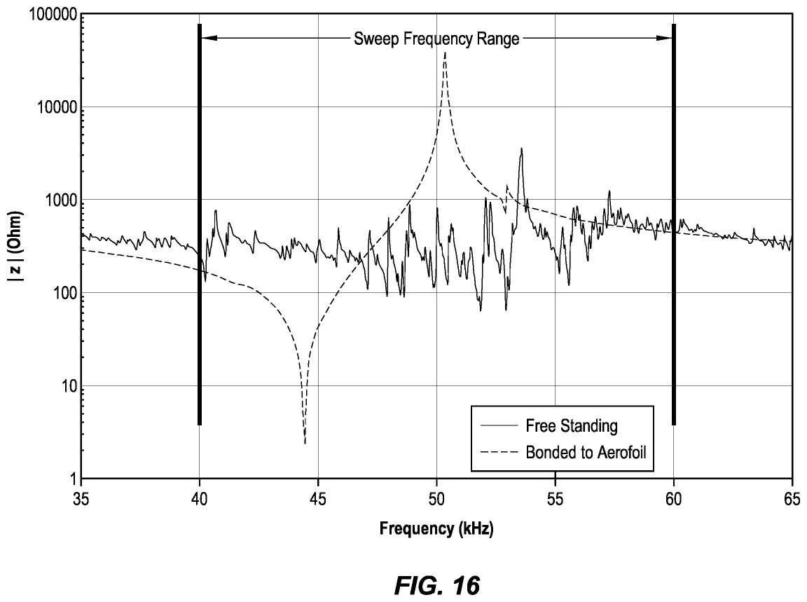

FIG. 16 illustrates the change in frequency response between an unbonded and bonded 50 mm PET disc. The sweep accommodates any changes in the spectrum as a consequence of ice accretion or temperature changes or local structural stiffness.

The speed of the frequency sweep also matters in the performances of the system. In preferred embodiments, the frequency is swept at a ratio of between 0.25 kHz/s and 3 kHz/s. In preferred embodiments, the ratio of the frequency sweep 1 kHz/s, which is optimal to obtain de-icing. A faster sweep (2 kHz/s) does not allow to fully use the resonance as the reaction time of the electronic system is slower. A slower sweep (0.5 kHz/s) increases the power usage of the system.

Piezo Phasing and Inversion.

Where multiple transducers are used within a system, the optimization of the piezo driving phase results in increased stress coverage for ice shedding. Piezo phasing can be controlled by the control system so that all of the piezos can operate at the same time, in anti-phase with each other or with a phase offset (between 0 and 180 degrees). More than two PETs in a system allows for multiple phasing offsets and inversions between the piezos. The offset will be decided based on position, geometry and icing conditions. Optimization is driven by test and design sensitivity analysis to identify piezo transducer spacing and phase operations so that shear stresses fields are optimal for deicing.

In embodiments where multiple transducers are used to de-ice the airfoil, a phase shift can be introduced. In this case the discs are driven with phase inversion, which is to say that while one disc is expanding, the other is contracting.

In some embodiments, phase inversion might maximize the produced stresses. Having two transducers excited in parallel can be counter-productive as interferences can occur between the different stress-modes and reduced the overall efficiency of the system.

In some embodiments, phase inversion reduces the variation in load on the driving system, since when driven pair wise, one transducer is always connected and one is disconnected.

Moreover, phase inversion will produce another stress pattern than phase synchronization, since the stress pattern that each transducer generates on the airfoil will superimpose. This also means that phase inversion can be used in combination with phase synchronization, but switching between the two methods the stress pattern changes and a larger fraction of the ice will likely experience stresses above the delamination/cracking threshold. The effect of this is similar to the frequency sweep, where the different frequencies will excite different vibrational/stress patterns in the airfoil. Individual phase variation can be performed for all transducers, but simple phase inversion should already lead to increased performances. It is also possible to vary between different phase shift configurations of the transducers, thus to produce even more different stress patterns.

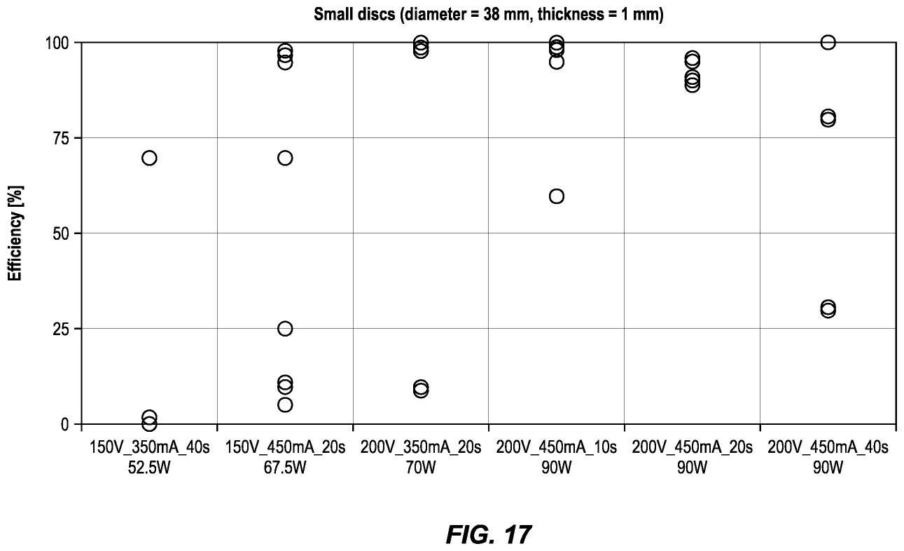

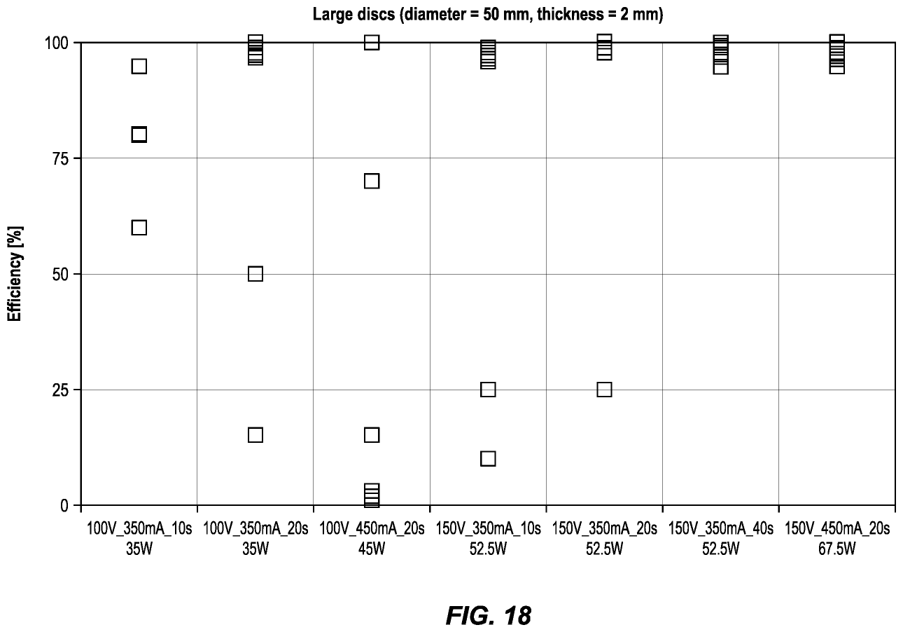

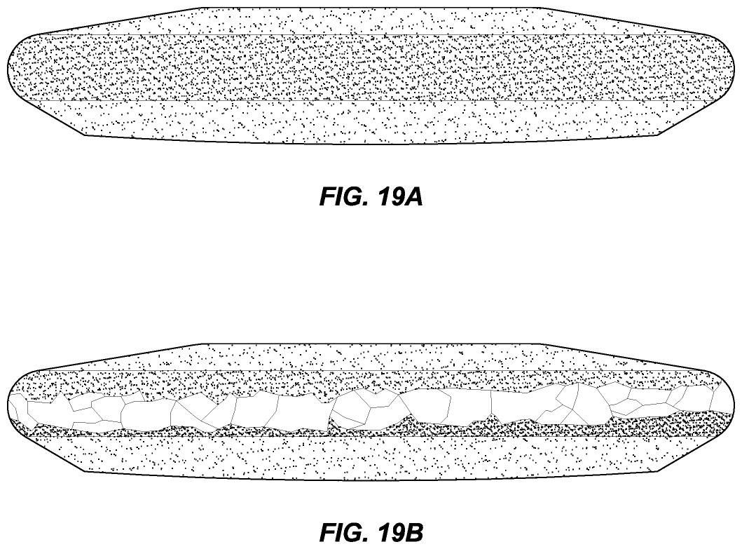

FIGS. 17 and 18 illustrate the de-icing efficiency of two sizes of PET discs. The maximum input power (given by a voltage and current limit) and the sweeping time (duration of one sweep) are controlled. The efficiency is estimated as the percentage of the leading edge where the ice has cracked. FIG. 19A shows an example of a leading edge with ice accretion and FIG. 19B shows the same leading edge with cracking. FIG. 19A illustrates an ice layer after 30 min accretion. FIG. 19B illustrates the de-icing results obtained with 2 PET, OD 50 mm, driven between 40-60 kHz with an apparent power limit of 35 W. As one can observe in FIG. 19B, the entire ice layer along the leading edge has been cracked, and in real flight conditions the high airflow will remove the pieces of ice once cracked. Or would aerodynamic pressure in the stagnation region hold the ice on? This coverage of de-icing was obtained after only one sweep.

The powers, represented on the X-axis of FIGS. 17 and 18, are for a 30 cm wide airfoil, and it is the power usage during excitation of the transducers; however, in preferred embodiments, the system is not in continuous anti-icing mode, but rather work in de-icing mode where it is switched on and off in a given periodicity or triggered by the thickness of accreted ice, for example 1 mm of ice. Hence the effective power consumption will be significantly less than the values in FIGS. 17 and 18. To estimate a value, a transducer consumption of 60 W is assumed and a sweep duration of 20 s. The activation periodicity is 10 min, with three sweeps performed each time. This leads to an effective power consumption of:

$${P}_{effective} = \frac{60 W \times 20 s \times 3}{600 s \times 0.3 m} = 20 \frac{W}{m}$$

From FIGS. 17 and 18 it can be seen that for each of the two types of PETs evaluated, a power threshold needs to be overcome to ensure reproducible performance of the system. The threshold of the smaller discs is close to the voltage limit of 200 V/mm thickness, which can explain the poor repeatability of the results. The excitation of the transducers also induces some heating at the PET's surface. This temperature increase is directly related to the input power and volume of transducers, therefore bigger transducers and lower power seems to be more suitable for integration into an aircraft. In other embodiments, more of the small transducers could be used. For example, three small discs might achieve the same de-icing performance as two bigger discs, with the same amount of power. Such performance optimization will have to be undertaken when planning the transducer deployment pattern.

In order to provide the required shear stress for delaminating the ice, the PETs require power to be supplied by an AC voltage having the following characteristics: 1). Voltage: up to some hundreds of Volts peak to peak (typically between 150 Vpp and 300 Vpp); 2). Current: up to some hundreds of milliAmps (typically between 100 mA and 500 mA); 3.) Frequency: between 10 kHz and 100 kHz (typically between 40 kHz and 80 kHz); 4.) AC voltage waveform is ideally a square wave that integrates into a triangular wave. However, for power supply design simplification, a square waveform may be used (a square waveform could be compliant with aircraft EMC requirements); 5.) good quality wires (for example, twisted shielded wires).

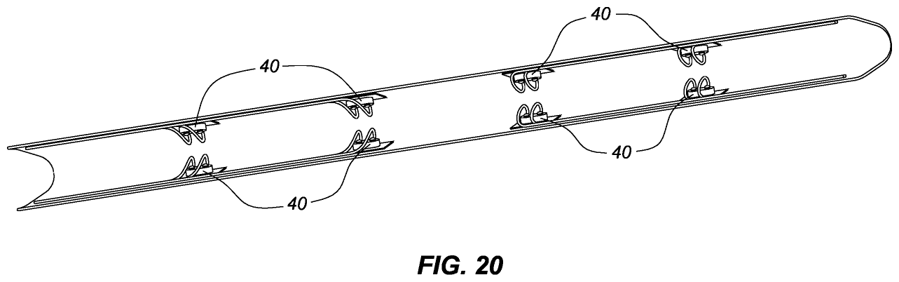

Returning to FIG. 8B, in some embodiments the AC voltage power is supplied from the 270 HVDC aircraft electrical network. FIG. 8B illustrates an electrical schematic for driving a PET 40. In order to provide this AC voltage for the PETs power supplies, a DC-DC converter 42 in combination with a downstream power inverter 44 is required. FIG. 20 shows the BC/CI fed from DC supplies.

In some embodiments, the buck converter can be fed by a transformer rectifier unit (TRU) from the aircraft AC supply to create the 270 HVDC supply.

In some embodiments, the DC-DC converter 42 can be a Buck converter. FIG. 8B illustrates a power system with a Buck converter. However, in other embodiments, the DC-DC converter 42 can be a Buck-boost converter, Forward converter or any combination thereof.

For de-icing both wings of an aircraft using PETs, a total electrical power of about 10 kW is required. This is a tenfold decrease of the 100 kW electro-thermal de-icing required power. In some embodiments, one 10 kW DC-DC converter (Buck converter) 42 can be designed to provide the total electrical power for de-icing both wings of the aircraft. In other embodiments, several Buck converters 42 may be required, but with a reduced power rating. For example, 2×5 kW rated Buck converters, 4×2.5 kW rated Buck converters, or 8×1.25 kW rated Buck converters may be used.

Depending on the embodiment, a single inverter 44 (a full H-bridge or Buck Conveter/Current Inverter) can power all the PETs of a dedicated airfoil zone. However, more inverters 44 may be used for more control of the individual PETs. For example, for improving de-icing efficiency, the PETs 40 could be operated with a phase shift between different PETs. To this end, an inverter 44 for each group of PETs that needs to be operated in a different phase could be used.

In embodiments with more than one group of PETs, each group of PETs can be operated by a separate inverter 44. Each inverter 44 has the capability of operating its group of PETs at a different phase or phase shift from the other PET groups. This phase shift can be constant (for example 180°=phase inversion), or variable. In embodiments where the phase shift is variable, it can be controlled for variation on a linearly varying mode, or according to a two-states changing mode (0/180°). This two-state changing mode can be made according to a pre-defined sequence method, or according to a pseudo-random method.

In different embodiments, different numbers of PET groups can be used. For example, 3, 4, 5 or 6 groups (=sub-frames) may be used. Each group of PETs being power by one inverter 44. For phase shift variation, this could be constant values, linear varying mode (each group having its dedicated linear variation depending time law), or two-states changing mode (each group changing at different times, on a pre-defined method or on a pseudo-random method).

Attachment of the PETs to the Aircraft.

In operation, the PET disc is placed inside the wing, coupled to the airfoil. FIG. 20 illustrates a cross-sectional view of an airfoil with a plurality of PETs attached to the inner skin. In preferred embodiments, the PET disc is glued to the airfoil using epoxy and/or a conductive epoxy. The location of the PET disc depends greatly on the available space from the wing's design, but it can be placed before or after the spar. Preferably, at least one PET disc is placed between two ribs, assuming space is available.

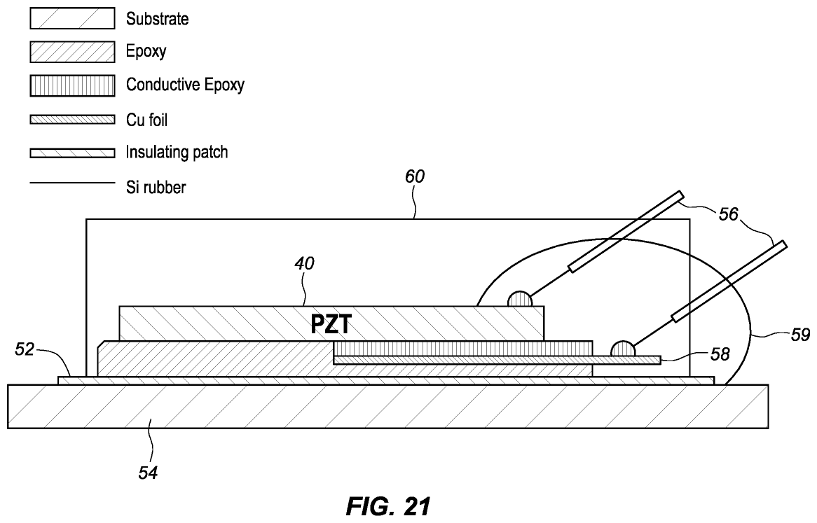

FIG. 21 illustrates a cross-section of the attachment of the PET 40 to the airfoil 54. The means of attaching the transducer to the skin of the wing and electrically contacting it shown in FIG. 21 enables good mechanical contact and electrical isolation from a metallic skin, while maintaining a simple transducer design for easy manufacturing, reliability and longevity.

In preferred embodiments, an electrically insulating composite patch 52 is placed on the substrate to avoid electrical contact between the transducer 40 and the airfoil 54. The insulating patch 52 covers the full surface area between the transducer 40 and the airfoil 54. In preferred embodiments, the insulating patch is placed on the metallic aerofoil to avoid electrical contact between the transducer and the wing surface. The terminal assembly is covered by an environmental insulation cap 60.

The PET disc 40 may be placed and glued to the composite patch 52 with epoxy.

In preferred embodiments, an electrically conductive sheet 58 may be glued to the bottom electrode of the transducer with conductive epoxy. In preferred embodiments, the electrically conductive sheet 58 may be a copper foil. The copper foil 58 does not cover the entire bottom of the transducer but rather just the bottom electrode. In other embodiments, the electrically conductive sheet 18 may be omitted and a layer of conductive epoxy may be used in its place.

The transducer may be connected to the driving system with electrical leads 56, which are respectively glued to the top electrode of the transducer 40 and the copper foil 58, which is an extension of the bottom electrode. In preferred embodiments, the electrical leads 56 may be welded to the electrode. In other embodiments, other electrical connectors 56 may be used. In preferred embodiments, conductive epoxy may be used to connect the cables 56 to the PET 40. A layer of silicone rubber 59 may be used to coat the connection points to supply stress relief and avoid detachment of the cables 56.

In yet another embodiment, a wrap-around electrode that traverses up the side and onto the top of the ceramic, to connect both wires to the top surface, may be used. This is not a preferred embodiment because, earlier investigations indicated that this design might increase the risk of the transducer cracking, as the asymmetrical design with the wrap-around results in a stress concentration in this region.

In yet other embodiments, the piezo transducer may be constrained. Constraining the PET can decrease the vibrational displacement while increasing the generated stress waves. To this end, constraining the PET may be a more advanced mounting method. There are several options for constraining the PET including but not limited to, placing a metal disc on top of the piezo disc, or using a metal ring to clamp the circumference of the PET.

For composite materials, the piezo could be placed inside the laminates, i.e. between laminate plies. Placing the PET completely inside the composite material would all a good transfer for the stresses created by the piezo the substrate.

While the focus of the embodiments herein is the development of a wing ice protection system that is based on the piezoelectric effect, performance considerations may entail the integration of an electro-thermal heater at the wing leading edge. As an example, a heated parting strip may be used along the leading edge may be used. Various embodiments can combine both electro-mechanical components with electro-thermal components. In some embodiments, ice-phobic coatings can also be used or combined with the various components.

Although the inventions have been described with reference to preferred embodiments and specific examples, it will readily be appreciated by those skilled in the art that many modifications and adaptations of the methods and devices described herein are possible without departure from the spirit and scope of the inventions as claimed hereinafter. Thus, it is to be clearly understood that this description is made only by way of example and not as a limitation on the scope of the invention.

What is claimed is:

1. A method of deicing an airfoil comprising:
coupling a plurality of piezo-electric transducers (PETs) to an inside surface of an airfoil;
electrically coupling the plurality of PETs to a DC-DC converter and a first inverter; and
sweeping the driving frequency of the plurality of PETs over a frequency range that spans at least 10 kHz-100 kHz.

2. The method of claim 1, wherein the plurality of PETs is divided into a first group and a second group and the first group is electrically coupled to the first inverter and the second group is coupled to a second inverter.

3. The method of claim 2, wherein the first inverter drives the first group at a phase shift to the second inverter driving the second group.

4. The method of claim 3, wherein the phase shift is 180 degrees.

5. The method of claim 3, wherein the amount of phase shift is repeatedly changing.

6. The method of claim 1, wherein the DC-DC converter is a buck converter.

7. The method of claim 2, wherein the first inverter and second inverter are both half bridges.

8. The method of claim 1, wherein the PETs have a diameter of 50 mm±2 mm.

9. The method of claim 1, wherein the PET has a thickness of 2 mm±0.1 mm.

10. The method of claim 1, wherein the first group and second group are both driven with a sine wave voltage.

11. A method of deicing an airfoil comprising:
coupling a plurality of piezo-electric transducers (PETs) to an inside surface of an airfoil;
electrically coupling the plurality of PETs to a DC-DC converter and a first inverter; and
sweeping the driving frequency of the plurality of PETs over a frequency range that spans at least 10 kHz-100 kHz;
wherein the plurality of PETs is divided into a first group and a second group and the first group is electrically coupled to the first inverter and the second group is coupled to a second inverter; and
wherein the first inverter drives the first group at a phase shift to the second inverter driving the second group.

12. The method of claim 11, wherein the phase shift is 180 degrees.

13. The method of claim 11, wherein the amount of phase shift is repeatedly changing.

14. The method of claim 11, wherein the DC-DC converter is a buck converter.

15. The method of claim 11, wherein the first inverter and second inverter are both half bridges.

16. The method of claim 11, wherein the PETs have a diameter of 50 mm±2 mm.

17. The method of claim 11, wherein the PET has a thickness of 2 mm±0.1 mm.

18. The method of claim 11, wherein the first group and second group are both driven with a sine wave voltage.
